(19) United States
(12) Patent Application Publication
(10) Pub. No.: US 2008/0296625 A1
(43) Pub. Date: Dec. 4, 2008

(54) Gallium nitride-on-silicon multilayered interface

(75) Inventors: Tingkai Li, Vancouver, WA (US); Douglas J. Tweet, Camas, WA (US); Jer-Shen Maa, Vancouver, WA (US); Sheng Teng Hsu, Camas, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America Inc.

(21) Appl. No.: 11/810,022

(22) Filed: Jun. 4, 2007

(51) Int. Cl. H01L 29/06; H01L 21/20

(52) U.S. Cl. 257/200; 438/478; 257/E29.005; 257/E21.09

(57) ABSTRACT

A multilayer thermal expansion interface between silicon (Si) and gallium nitride (GaN) films is provided, along with an associated fabrication method. The method provides a (111) Si substrate and forms a first layer of a first film overlying the substrate. The Si substrate is heated to a temperature in the range of about 300 to 800° C., and the first layer of a second film is formed in compression overlying the first layer of the first film. Using a lateral nanoheteroepitaxy overgrowth (LNEO) process, a first GaN layer is grown overlying the first layer of second film. Then, the above-mentioned processes are repeated: forming a second layer of first film; heating the substrate to a temperature in the range of about 300 to 800° C.; forming a second layer of second film in compression; and, growing a second GaN layer using the LNEO process.

### BACKGROUND OF THE INVENTION

1. Field of the Invention

This invention generally relates to integrated circuit (IC) fabrication and, more particularly to a gallium nitride-on-silicon multilayer interface and associated fabrication process.

2. Description of the Related Art

Gallium nitride (GaN) is a Group III/Group V compound semiconductor material with wide bandgap (3.4 eV), which has optoelectronic, as well as other applications. Like other Group III nitrides, GaN has a low sensitivity to ionizing radiation, and so, is useful in solar cells. GaN is also useful in the fabrication of blue light-emitting diodes (LEDs) and lasers. Unlike previous indirect bandgap devices (e.g., silicon carbide), GaN LEDs are bright enough for daylight applications. GaN devices also have application in high power and high frequency devices, such as power amplifiers.

GaN LEDs are conventionally fabricated using a metalorganic chemical vapor deposition (MOCVD) for deposition on a sapphire substrate. Zinc oxide and silicon carbide (SiC) substrate are also used due to their relatively small lattice constant mismatch. However, these substrates are expensive to make, and their small size also drives fabrication costs. For example, the state-of-the-art sapphire wafer size is relatively small when compared to silicon wafers. The most commonly used substrate for GaN-based devices is sapphire. The low thermal and electrical conductivity constraints associated with sapphire make device fabrication more difficult. For example, all contacts must be made from the top side. This contact configuration complicates contact and package schemes, resulting in a spreading-resistance penalty and increased operating voltages. The poor thermal conductivity of sapphire [0.349 (W/cm-° C.)], as compared with that of Si [1.49 (W/cm-° C.)] or SiC, also prevents efficient dissipation of heat generated by high-current devices, such as laser diodes and high-power transistors, consequently inhibiting device performance.

To minimize costs, it would be desirable to integrate GaN device fabrication into more conventional Si-based IC processes, which has the added cost benefit of using large-sized (Si) wafers. Si substrates are of particular interest because they are less expansive and they permit the integration of GaN-based photonics with well-established Si-based electronics. The cost of a GaN heterojunction field-effect transistor (HFET) for high frequency and high power application could be reduced significantly by replacing the expensive SiC substrates that are conventionally used.

FIG. 1 is a graph depicting the lattice constants of GaN, Si, SiC, AlN and sapphire (prior art). There are two fundamental problems associated with GaN-on-Si device technology. First, there is a lattice mismatch between Si and GaN. The difference in lattice constants between GaN and Si, as shown in the figure, results in a high density of defects from the generation of threading dislocations. This problem is addressed by using a buffer layer of AlN, InGaN, AlGaN, or the like, prior to the growth of GaN. The buffer layer provides a transition region between the GaN and Si.

FIG. 2 is a graph depicting the thermal expansion coefficients (TECs) of GaN, Si, SiC, AlN, and sapphire (prior art). An additional and more serious problem exists with the use of Si, as there is also a thermal mismatch between Si and GaN. GaN-on-sapphire experiences a compressive stress upon cooling. Therefore, film cracking is not as serious of an issue as GaN-on-Si, which is under tensile stress upon cooling, causing the film to crack when the film is cooled down from the high deposition temperature. The thermal expansion coefficient mismatch between GaN and Si is about 54%.

The film cracking problem has been analyzed in depth by various groups, and several methods have been tested and achieve different degrees of success. The methods used to grow crack-free layers can be divided into two groups. The first method uses a modified buffer layer scheme. The second method uses an in-situ silicon nitride masking step. The modified buffer layer schemes include the use of a graded AlGaN buffer layer, AlN interlayers, and AlN/GaN or AlGaN/GaN-based superlattices.

Although the lattice buffer layer may absorb part of the thermal mismatch, the necessity of using temperatures higher than 1000° C. during epi GaN growth and other device fabrication processes may cause wafer deformation. The wafer deformation can be reduced with a very slow rate of heating and cooling during wafer processing, but this adds additional cost to the process, and doesn't completely solve the thermal stress and wafer deformation issues.

It is generally understood that a buffer layer may reduce the magnitude of the tensile growth stress and, therefore, the total accumulated stress. However, from FIG. 2 it can be seen that there is still a significant difference in the TEC of these materials, as compared with GaN. Therefore, thermal stress remains a major contributor to the final film stress.

It would be advantageous if the thermal mismatch problem associated with GaN-on-Si device technology could be practically eliminated by pre-compressing a thermal interface interposed between the GaN and Si layers.

### SUMMARY OF THE INVENTION

The “a” lattice constants of GaN, Si, and sapphire are about 0.319 nanometers (nm), 0.543 nm, and 0.476 nm, respectively. For GaN on Si(111), the relevant comparison is a_{GaN} to a_{Si}/(2^{1/2}) giving a mismatch of about −20.4% at room temperature. For GaN on (0001) oriented sapphire, the relevant comparison is (3/2)^{1/2}×a_{GaN} to aₛₐₚₚₕᵢᵣₑ/2, leading to a mismatch of about +14% at room temperature. Thus, the lattice mismatch between GaN and sapphire is less severe than that between GaN and silicon.

The thermal expansion coefficients for GaN, Si, and sapphire are 4.3e-6 at 300K for a, 3.9e-6 at 300K for c, 2.57e-6 at 300K, and ˜4.0e-6 at 300K for both a and c, respectively, but rises very rapidly with temperature. The thermal expansion mismatch between GaN and Si is more severe than that between GaN and sapphire, as the former system results in GaN films under tensile strain (leading to cracking), and the latter system produces GaN under compressive stress, which causes fewer problems. Therefore, a new structure to release the thermal expansion related stress would be useful for growing GaN on silicon substrates.

The GaN growth temperature is normally 1050° C. or higher. Therefore, when the wafer is cooled down from the growth chamber, the GaN shrinks faster than the silicon substrate, but is partly restrained by the silicon. As a result, a tensile stress is applied to the GaN film that may cause the GaN film to crack. However, if a pre-compressed layer is formed on Si substrates at GaN growth temperatures, the pre-compressed layer reduces the tensile stress as the GaN film is cooled down from growth temperature, and a crack-free GaN film on Si can be made. Multilayered films may be initially grown at a low temperature. Then, by increasing the growth temperatures, a compressed layer of epitaxial GaN can be formed on a Si substrate.

Accordingly, a method is provided for forming a multilayer thermal expansion interface between silicon (Si) and gallium nitride (GaN) films. The method provides a (111) Si substrate and forms a first layer of a first film overlying the substrate. The first film may be either relaxed or in compression. The first film material may be AlN, AlGaN, an AlN/graded AlGaN (Al₁₋ₓGaₓN (0<x<1)) stack, or an AlN/graded AlGaN/GaN stack. The Si substrate is heated to a temperature in the range of about 300 to 800° C., and the first layer of a second film is formed in compression overlying the first layer of the first film. The second film may be a material such as Al₂O₃, InP, SiGe, GaP, GaAs, AlN, AlGaN, or GaN. Using a lateral nanoheteroepitaxy overgrowth (LNEO) process, a first GaN layer is grown overlying the first layer of second film. Then, the above-mentioned processes are repeated: forming a second layer of first film; heating the substrate to a temperature in the range of about 300 to 800° C.; forming a second layer of second film in compression; and, growing a second GaN layer using the LNEO process.

Generally, the first and second films each have a thickness in the range of about 5 to 500 nanometers (nm). The first GaN layer has a thickness in a range of 0.3 to 1 micrometers, while the second GaN layer has a thickness in a range of 1 to 4 micrometers. Both the first and second GaN layers are grown by heating the Si substrate to a temperature in a range of 1000 to 1200° C.

Additional details of the above-mentioned method and a GaN-on-Si multilayer thermal expansion interface are provided below.

### BRIEF DESCRIPTION OF THE DRAWINGS

FIG. 1 is a graph depicting the lattice constants of GaN, Si, SiC, AlN and sapphire (prior art).

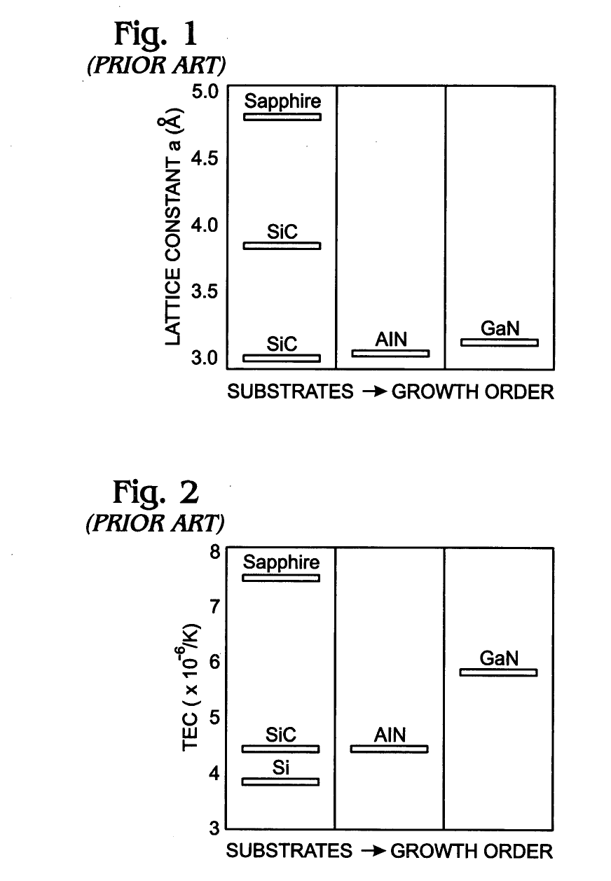

FIG. 2 is a graph depicting the thermal expansion coefficients (TECs) of GaN, Si, SiC, AlN, and sapphire (prior art).

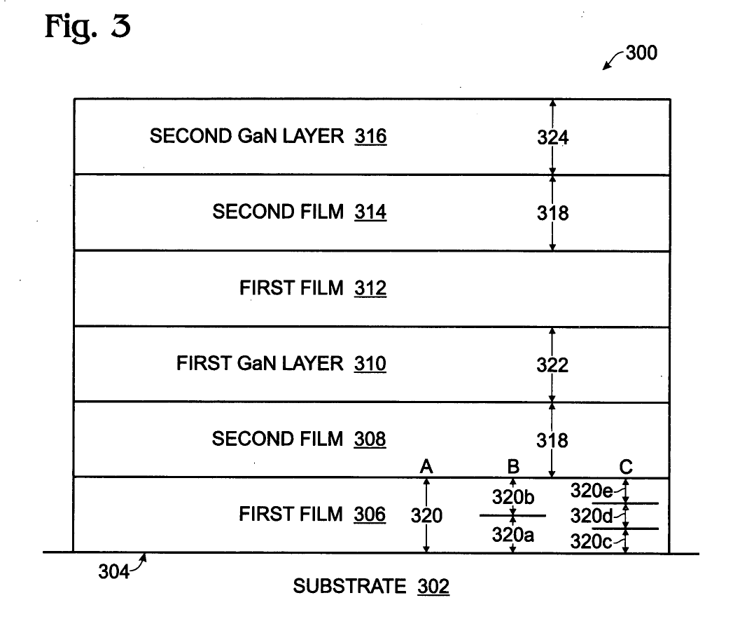

FIG. 3 is a partial cross-sectional view of a silicon (Si)-to-gallium nitride (GaN) multilayer thermal expansion interface.

Table 1 and FIG. 4 depict the lattice and thermal expansion coefficient data, respectively, of GaN-on-Si related materials.

FIGS. 5 through 8 depict fabrication steps in the completion of the interface of FIG. 3.

FIG. 9 is a flowchart illustrating a method for forming a multilayer thermal expansion interface between Si and GaN films.

### DETAILED DESCRIPTION

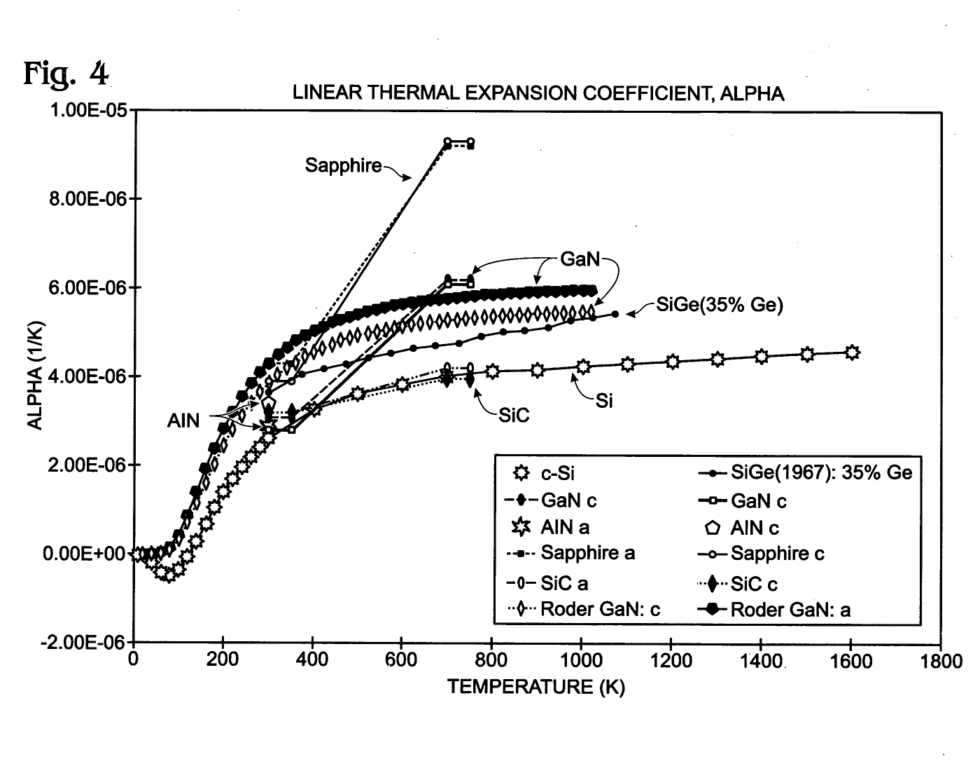

FIG. 3 is a partial cross-sectional view of a silicon (Si)-to-gallium nitride (GaN) multilayer thermal expansion interface. The interface 300 comprises a (111) Si substrate 302 with a top surface 304. A first layer of a first film 306 overlies the Si substrate 302. The first film 306 may either be relaxed or in compression. The first film may be a material such as AlN, AlGaN, an,AlN/graded AlGaN (Al₁₋ₓGaₓN (0<x<1)) stack, or a AlN/graded AlGaN/GaN stack. A first layer of a second film 308 is in compression overlying the first film 306. The second film 308 may be a material such as Al₂O₃, InP, SiGe, GaP, GaAs, AlN, AlGaN, or GaN. A first GaN layer 310 overlies the first layer of second film. As explained in detail below, the GaN film is formed using a lateral nanoheteroepitaxy overgrowth (LNEO) process. A second layer of first film 312 overlies the first GaN layer 310. The materials choices for the second layer of the first film 312 are the same as for the first layer 306. A second layer of second film 314 is in compression overlying the second layer of first film 312. The materials choices for the second layer of the second film 314 are the same as for the first layer 308. A second GaN layer 316 overlies the second layer of second film 314.

The second films 308/314 each have a thickness 318 in the range of about 5 to 500 nanometers (nm). If the first films 306/312 are an AlN film (see detail A), they each have a thickness 320 in the range of about 5 to 500 nm. Although the thickness for the first film second layer is not specifically shown, the thickness is in same ranges as the first layer 310. If the first films 308/312 are an AlN/graded AlGaN stack (see detail B), the AlN film has a thickness 320a in the range of about 5 to 500 nm and the AlGaN has a thickness 320b in the range of about 20 to 500 nm. Although the thicknesses for the first film second layers are not specifically shown, their thicknesses are in same ranges as the first layer 310. If the first films 306/312 are an AlN/AlGaN/GaN stack (see detail C), the AlN film has a thickness 320c in the range of about 5 to 500 nm, the AlGaN is graded and has a thickness 320d in the range of about 5 to 500 nm, and the GaN has a thickness 320e in the range of about 5 to 500 nm. Although the thicknesses for the first film second layers are not specifically shown, their thicknesses are in same ranges as the first layer 310. Typically, the first GaN layer 310 has a thickness 322 in the range of 0.3 to 1 micrometers, and the second GaN layer 318 has a thickness 324 in the range of 1 to 4 micrometers.

### Functional Description

A pre-compressed layer is formed on Si substrates at GaN growth temperatures. The pre-compressed layer reduces the tensile stress as the GaN film is cooled down from growth temperature, and a crack-free GaN film on Si can be made. Materials such as Al₂O₃, Si₁₋ₓGeₓ, InP, GaP, GaAs, AlN, AlGaN, and GaN may be initially grown at low temperature, with a subsequent increase to higher temperatures to form a compressed layer. The compressed layer acts as an interface between an epi GaN film and a Si substrate.

When a coating is cooled after deposition, and its thermal expansion coefficient, α_{c}, is larger than that of the substrate, αₛ, (as in the case of GaN on Si), the coating is under tensile strain. As a result, the uncracked film-substrate composite bends, having a radius of curvature, ρ, as

1/ρ=(αₛ−α_{c})(T_{f}−T_{g})/[h/2+2(E_{c}*I_{c}+Eₛ*Iₛ)/h(1/E_{c}*t_{c}+1/Eₛ*tₛ)] (1)

where T_{f} is the final temperature after cooling; T_{g} is the growth temperature; t_{c} and tₛ are the individual coating and substrate thicknesses; h is the total thickness (h=t_{c}+tₛ); I is the moment of inertia, I=t³/12; and E* is the effective modulus of elasticity. These conditions apply for wide layers and plane strain conditions E*=E/(12−v²), where E is the Young's modulus of elasticity and v is the Poisson's ratio.

From formula (1), the quantity [h/2+2(E_{c}*I_{c}+Eₛ*Iₛ)/h(1/E_{c}*t_{c}+1/Eₛ*tₛ)] is called A. A decreases with an increase in the thickness of the coating materials. But if tc<<ts, the coating thickness effect for A can be ignored. The formula (1) changes to

1/ρ=(αₛ−α_{c})(T_{f}−T_{g})/A (2)

Since the coating is thin (t_{c}<0.1 tₛ), the predicted inplane normal stress in the uncracked coating is uniform and is given by

σₚ=1/ρ[2/ht_{c}(E_{c}*I_{c}+Eₛ*Iₛ)+E_{c}*t_{c}/2] (3)

The quantity [2/ht_{c}(E_{c}*I_{c}+Eₛ*Iₛ)+E_{c}*t_{c}/2] is called B. B increases with an increase in the thickness of coating materials. The formula (3) changes to

σₚ=B(αₛ−α_{c})(T_{f}−T_{g})/A (4)

Let B/A=R, which increases with an increase in the thickness of the coating materials. The formula (4) can be written as

σₚ=R(αₛ−α_{c})(T_{f}−T_{g}) (5)

From formula (5), when the thermal expansion coefficient of the coating material is larger than that of the substrate and is deposited at higher temperatures, the coating materials are under tensile stress (σₚ>0) after cooling down. In contrast, when the thermal expansion coefficient of the coating material is larger than that of the substrate and deposited at lower temperatures, the coating materials is under compressive stress (σₚ<0) when heated to higher temperatures.

Therefore, if materials are grown with a higher thermal expansion coefficient on Si substrates at lower temperatures, the coated materials will be under compression when the wafer is heated to higher temperature, such as the temperatures required for GaN growth. During the wafer cooling down process, the compressed layer reduces the tensile stress of the overlying GaN films, and a crack-free GaN film on a Si substrate is formed.

Table 1 and FIG. 4 depict the lattice and thermal expansion coefficient data, respectively, of GaN on Si related materials. From this data, it can be seen that Al₂O₃, Si1-xGex, InP, GaP, GaAs, AlN, AlGaN, and GaN, etc., may be used to make a pre-compressed layer on Si substrates. Ge, InP, GaP, and GaAs, etc., can be grown at lower temperatures. AlN has been successfully grown on Si at room

TABLE 1
Crystal structure, lattice parameters, and thermal
expansion coefficient of selected semiconductor materials

| | | Lattice | Thermal | | | |
|---|---|---|---|---|---|---|
| | Crystal | parameter | Expansion Coeff. | Dielectric | Refractive | Bandgap |
| Materials | Structure | (Å) | (×10⁻⁶/° C.)@25° C. | constant (ε) | Index (n) | (eV)@25° C. |
| GaN | W | a = 3.190(1) | a: 4.3(7) | 9.5 | | 3.34(1) |
| | | c = 5.189(1) | c: 3.9(7) | | | |
| GaN | Z | a = 4.52 | | | | 3.2-3.3 |
| AlN | W | a = 3.111(1) | 2.0(5.3) | 8.5-9 | | 6.02(1) |
| | | c = 4.978(1) | 3.0(4.2) | | | |
| AlN | Z | a = 4.38 | | | | 5.11 |
| Al₂O₃ | R | a = 4.758 | 4.0(9) | 4.5-8.4(1) | 1.76(4) | >8(4) |
| | | c = 12.991 | 7.5, 8.3(4) | 8.6-10.6(4) | | |
| Si | D | a = 5.431 | 2.57(8) | 11.8(1) | 3.49(1) | 1.107(1) |
| | | | 4.68(1), 3.59(6), | | | |
| GaAs | Z | a = 5.653(1) | 5.4(1) | 13.2(1) | | 1.4 |
| 6H—SiC | W | a = 3.076(1) | 3.3(4.2) | 10 | 2.654(1) | 2.9 |
| | | c = 5.048(1) | (4.7) | | | |
| 3c-SiC | Z | a = 4.348(1) | 2.7(2.9) | 9.7 | 2.697(1) | 2.3(1) |
| InP | Z | a = 5.869(1) | 4.6(1) | 12.4(1) | 3.1(1) | 1.27(1) |
| InN | W | a = 3.533(1) | 4 | | | 2.0(1) |
| | | c = 5.693(1) | | | | 1.89 |
| InN | Z | a = 4.98 | | | | 2.2 |
| GaP | Z | a = 5.451(1) | 5.3(1) | 11.1(1) | 3.2(1) | 2.24(1) |
| MgO | C | a = 4.216(1) | 10.5, 13.5(4) | 9.65(4) | 1.74(4) | >7.8(4) |
| ZnO | W | a = 3.25(1) | 2.9 | | | 3.2(1) |
| | | c = 5.207(1) | 4.75 | | | |

temperature. Al₂O₃ can be coated on Si substrates by anodized alumina oxide (AAO) processes, GaN can also be grown below 700° C., and the temperature increased for epitaxial (epi) GaN growth. Therefore, there are several materials that can be initially grown on Si at low temperatures, with an increase to higher temperatures, to form a compressed layer for epi GaN deposition.

An AAO process may, for example, deposit a high quality aluminum film on a silicon substrate using E-beam evaporation, with a film thickness of 0.5 to 1.5 μm. Both oxalic and sulfuric acid may be used in the anodization process. In a first step, the aluminum coated wafers are immersed in acid solution at 0° C. for 5 to 10 minutes for an anodization treatment. Then, the alumina formed in the first anodic step is removed by immersion in a mixture of H₃PO₄ (4-16 wt %) and H₂Cr₂O₄ (2-10 wt %) for 10 to 20 minutes. After cleaning the wafer surface, the aluminum film is exposed to a second anodic treatment, the same as the first step described above. Then, the aluminum film may be treated in 2-8 wt % H₃PO₄ aqueous solution for 15 to 90 minutes. The processes may be used to form a porous alumina template, if desired.

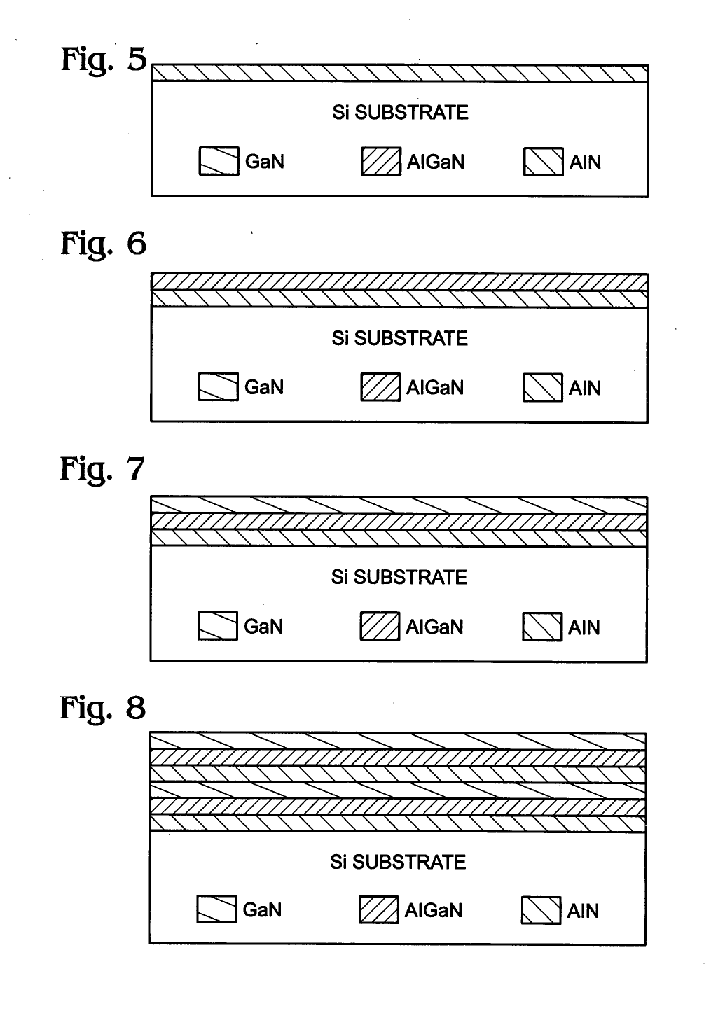

FIGS. 5 through 8 depict fabrication steps in the completion of the interface of FIG. 3. The starting wafer is <111> oriented silicon substrate. After cleaning the silicon substrate, for example using an in situ hydrogen treatment, a first film layer may be deposited. The first film may be high quality AlN (as shown), AlN/graded AlGaN, or AlN/graded AlGaN/GaN, see FIG. 5.

Then, a second film material of Al₂O₃, InP, SiGe, GaP, GaAs, AlN, AlGaN (as shown), or GaN is deposited at a low temperature, from 300-800° C., see FIG. 6. In FIG. 7, epitaxial GaN is grown at a higher temperature of about 1000-1200° C.

The steps depicted in FIGS. 6 and 7 are repeated. If the surface of the LNEO GaN is not flat enough for device fabrication, than an optional chemical-mechanical polish (CMP) may be performed. After CMP, an additional GaN layer may be grown to form a very smooth GaN film for device fabrication, as shown in FIG. 8.

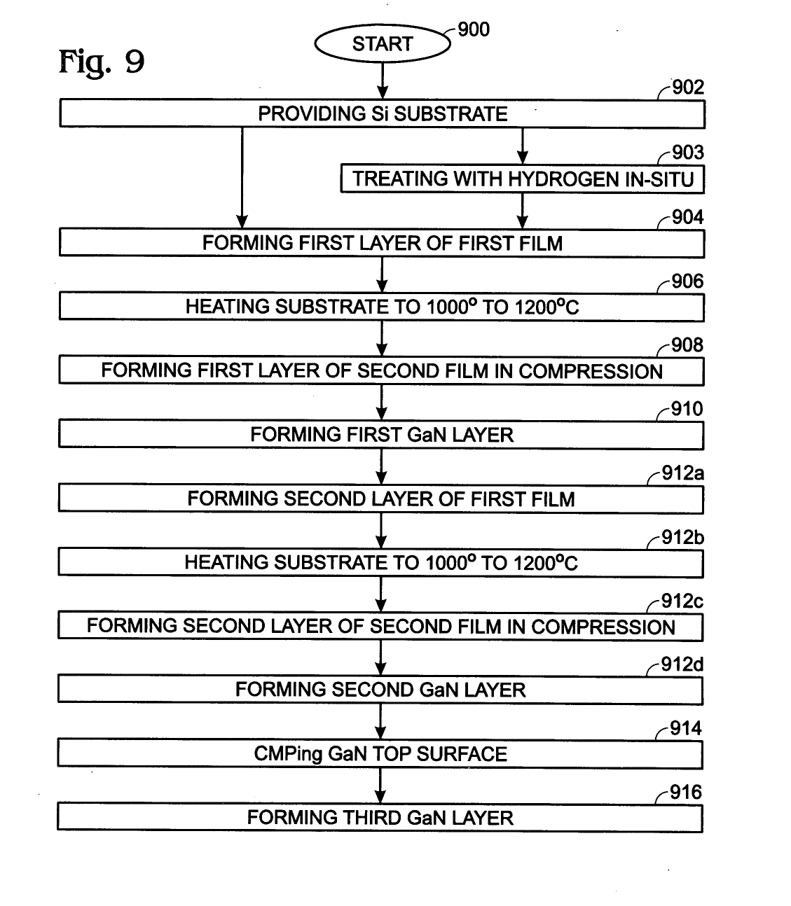

FIG. 9 is a flowchart illustrating a method for forming a multilayer thermal expansion interface between Si and GaN films. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 900.

Step 902 provides a (111) Si substrate. Prior to forming the first layer of first film overlying the Si substrate, Step 903 optionally cleans a Si substrate top surface using an in-situ hydrogen treatment. Step 904 forms a first layer of a first film of a material such as AlN, AlGaN, an AlN/graded AlGaN (Al₁₋ₓGaₓN (0<x<1)) stack, or an AlN/graded AlGaN/GaN stack, overlying the Si substrate. The first film may be either formed as a relaxed or compressed film. If relaxed, the first film may be formed by heating the substrate to a temperature in the range of 1000 to 1200° C. in one thermal cycle, and then cooling to a temperature of less than 500° C.

Step 906 heats the Si substrate to a temperature in a range of about 300 to 800° C., and Step 908 forms a first layer of a second film in compression overlying the first layer of the first film. The second film may be a material such as Al₂O₃, InP, SiGe, GaP, GaAs, AlN, AlGaN, or GaN. Using a LNEO process, Step 910 grows a first GaN layer overlying the first layer of second film. Step 912 repeats the above-mentioned processes of Steps 904 through 910. Step 912a forms a second layer of first film. The materials are the same as those mentioned in Step 904. The second layer of first film may be either relaxed or compressed. Step 912b heats the substrate to a temperature in the range of about 300 to 800° C. Step 912c forms a second layer of second film in compression. The materials are the same as those mentioned in Step 908. Step 912d grows a second GaN layer using the LNEO process.

Generally, the second films formed in Steps 906 and 912c have a thickness in the range of about 5 to 500 nm. If the first films formed in Steps 904 and 912a are AlN, they typically have a thickness in the range of about 5 to 500 nm. If the first films formed in Steps 904 and 912a are AlN/graded AlGaN stacks, the AlN film has a thickness in the range of about 5 to 500 nm and the AlGaN has a thickness in the range of about 20 to 500 nm. If the first films formed in Steps 904 and 912a are AlN/AlGaN/GaN stacks, the AlN film has a thickness in the range of about 5 to 500 nm, the AlGaN is graded and has a thickness in the range of about 5 to 500 nm, and the GaN has a thickness in the range of about 5 to 500 nm.

In one aspect, growing the second GaN layer in Step 912d includes forming a GaN second layer top surface. Then, Step 914 performs a CMP on the GaN second layer top surface, and Step 916 grows a third GaN layer on the GaN second layer top surface using the LNEO process.

In another aspect, growing the first and second GaN layers in Step 910 and 912d includes heating the Si substrate to a temperature in a range of 1000 to 1200° C. Typically, the first GaN layer grown in Step 904 has a thickness in the range of 0.3 to 1 micrometers. The second GaN layer typically has a thickness in the range of 1 to 4 micrometers.

A GaN-on-Si multilayer thermal expansion interface and associated fabrication process have been provided. Some examples and materials, dimensions, and process steps have been given to illustrate the invention. However, the invention is not limited to merely these examples. Other variations and embodiments of the invention will occur to those skilled in the art.

We claim:

1. A method for forming a multilayer thermal expansion interface between silicon (Si) and gallium nitride (GaN) films, the method comprising:
providing a (111) Si substrate;
forming a first layer of a first film selected from a group consisting of AlN, AlGaN, an AlN/graded AlGaN (Al₁₋ₓGaₓN (0<x<1)) stack, and a AlN/graded AlGaN/GaN stack, overlying the Si substrate;
heating the Si substrate to a temperature in a range of about 300 to 800° C.;
forming a first layer of a second film in compression overlying the first layer of the first film, the second film selected from a group consisting of Al₂O₃, InP, SiGe, GaP, GaAs, AlN, AlGaN, and GaN;
using a lateral nanoheteroepitaxy overgrowth (LNEO) process, growing a first GaN layer overlying the first layer of second film; and,
repeating the above-mentioned processes, forming a second layer of first film, heating the substrate to a temperature in the range of about 300 to 800° C., forming a second layer of second film in compression, and growing a second GaN layer using the LNEO process.

2. The method of claim 1 wherein forming the second films includes forming second films having a thickness in a range of about 5 to 500 nanometers (nm).

3. The method of claim 1 wherein forming the first films includes forming AlN films having a thickness in a range of about 5 to 500 nm.

4. The method of claim 1 wherein forming the first films includes forming AlN/graded AlGaN stacks, where the AlN film has a thickness in a range of about 5 to 500 nm and the AlGaN has a thickness in a range of about 20 to 500 nm.

5. The method of claim 1 wherein forming the first films includes forming AlN/AlGaN/GaN stacks, where the AlN film has a thickness in a range of about 5 to 500 nm, the AlGaN is graded and has a thickness in a range of about 5 to 500 nm, and the GaN has a thickness in a range of about 5 to 500 nm.

6. The method of claim 1 wherein growing the second GaN layer includes forming a GaN second layer top surface; and,
the method further comprising:
performing a chemical mechanical polishing (CMP) on the GaN second layer top surface; and,
growing a third GaN layer on the GaN second layer top surface using the LNEO process.

7. The method of claim 1 further comprising:
prior to forming the first layer of first film overlying the Si substrate, cleaning a Si substrate top surface using an in-situ hydrogen treatment.

8. The method of claim 1 wherein growing the first and second GaN layers includes heating the Si substrate to a temperature in a range of 1000 to 1200° C.

9. The method of claim 1 wherein growing the first GaN layer includes growing a GaN layer having a thickness in a range of 0.3 to 1 micrometers; and,
wherein growing the second GaN layer includes growing a GaN layer having a thickness in a range of 1 to 4 micrometers.

10. The method of claim 1 wherein forming the first films includes forming first films selected from a group consisting of relaxed and compressed first films.

11. The method of claim 10 wherein forming the first films includes forming relaxed first films in response to heating the substrate to a temperature in a range of 1000 to 1200° C.

12. A silicon (Si)-to-gallium nitride (GaN) multilayer thermal expansion interface, the interface comprising:
a (111) Si substrate;
a first layer of a first film selected from a group consisting of AlN, AlGaN, an AlN/graded AlGaN (Al₁₋ₓGaₓN (0<x<1)) stack, and an AlN/graded AlGaN/GaN stack, overlying the Si substrate;
a first layer of a second film in compression overlying the first film, the second film selected from a group consisting of Al₂O₃, InP, SiGe, GaP, GaAs, AlN, AlGaN, and GaN;
a first GaN layer overlying the first layer of second film;
a second layer of first film overlying the first GaN layer;
a second layer of second film in compression overlying the second layer of first film; and,
a second GaN layer overlying the second layer of second film.

13. The interface of claim 12 wherein the second films have a thickness in a range of about 5 to 500 nanometers (nm).

14. The interface of claim 12 wherein the first films are an AlN film having a thickness in a range of about 5 to 500 nm.

15. The interface of claim 12 wherein the first films are an AlN/graded AlGaN stack, where the AlN film has a thickness in a range of about 5 to 500 nm and the AlGaN has a thickness in a range of about 20 to 500 nm.

16. The interface of claim 12 wherein the first films are an AlN/AlGaN/GaN stack, where the AlN film has a thickness in a range of about 5 to 500 nm, the AlGaN is graded and has a thickness in a range of about 5 to 500 nm, and the GaN has a thickness in a range of about 5 to 500 nm.

17. The interface of claim 12 wherein the first GaN layer has a thickness in a range of 0.3 to 1 micrometers; and, wherein the second GaN layer has a thickness in a range of 1 to 4 micrometers.

18. The interface of claim 12 wherein the first films are selected from a group consisting of relaxed and compressed first films.
